(19) United States
(12) Patent Application Publication
(10) Pub. No.: US 2007/0102792 A1
(43) Pub. Date: May 10, 2007

(54) MULTI-LAYER CRACK STOP STRUCTURE

(76) Inventor: Ping-Chang Wu, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,511

(22) Filed: Mar. 31, 2006

Related U.S. Application Data
(63) Continuation-in-part of application No. 11/163,982, filed on Nov. 7, 2005.

(51) Int. Cl. H01L 23/544

(52) U.S. Cl. 257/620

(57) ABSTRACT

A multi-layer crack stop structure is described, disposed entirely in a die, entirely in a scribe line region outside the die, or partially in the die and partially in the scribe line region. The multi-layer crack stop structure is formed by stacking multiple layers of hollow crack stop units. The multi-layer crack stop structure can effectively prevent some damages like chipping, delamination or peeling-off from occurring to the active circuit region when the wafer is being sawn or when the die is subject to thermal cycles for testing, so that a better die can be obtained and the reliability of the packaged die can be significantly improved.

### CROSS-REFERENCE TO RELATED APPLICATION

This application is the continuation-in-part application of the U.S. patent application Ser. No. 11/163,982, filed on Nov. 07, 2005. All disclosures are incorporated herewith by reference.

### BACKGROUND OF THE INVENTION

1. Field of the Invention

This invention relates to a wafer structure, and more particularly, to a multi-layer crack stop structure formed on a wafer. The multi-layer crack stop structure is disposed surrounding the active circuit region of a die, so as to prevent the active circuit region from being damaged when the wafer is being sawn or when the die is subject to thermal cycles for testing, which significantly improves the reliability of the packaged die.

2. Description of the Related Art

Along with the continuous development of new technology, integrated circuits (IC) had been widely applied in our daily life. An IC product is typically fabricated with three processes: wafer preparation, IC formation and IC packaging. A die sawing process is performed at the beginning of an IC packaging process.

A wafer generally includes many horizontal and vertical scribe lines that define many dies. After the device fabrication is finished on a wafer, a diamond blade is used to saw the wafer along the scribe lines to obtain separate dies. Because many material layers having different properties are formed on a wafer, damages like chipping or peeling-off easily occur to the material layers in a die beside the scribe lines during the wafer sawing or the thermal cycles for testing a separated die. The chipping and delamination problem becomes even worse if the wafer is formed with a low-k/Cu structure thereon. Moreover, when the device dimension is scaled down, the scribe line becomes narrower so that the problem of sawing cracks penetrating into the operating metal or the active circuit region is more serious. Thus, the reliability of the packaged die is deteriorated.

In another prior-art wafer dividing method, laser grooving is introduced replacing the blade sawing. However, the laser grooving method also has some problems. For example, when the wafer layers include a metal layer, it is difficult to completely remove the metal layer with laser so that some debris still remains to stain the dies. In addition, a large heat effect area is formed beside the scribe line during the laser grooving, greatly impacting the reliability of the dies. Moreover, a laser grooving device is 2-3 times more expensive than a diamond blade device, making the cost of such method much higher.

Accordingly, a crack stop structure formed on a wafer for preventing damages in blade sawing was disclosed in U.S. Pat. No. 5,530,280. As shown in FIG. 1, two active circuit regions 110 and 120 are defined on a wafer 100, and two dielectric layers 132 and 134 are formed thereon. The dielectric layer 132 has therein a metal contact 112 and two tungsten rings 142 and 152. The dielectric layer 134 has therein a metal contact 116, interconnect metals 114, 144 and 154, and two tungsten rings 146 and 156 respectively having hollow rings 145 and 155. Interconnect metals 118, 148 and 158 are formed on the dielectric layer 134, and a scribe line 160 is defined between 148 and 158.

The structure for protecting the active circuit region 110 from a crack includes the tungsten rings 142 and 146 and the interconnect metals 144 and 148. The structure for protecting the active circuit region 120 from a crack includes the tungsten rings 152 and 156 and the interconnect metals 154 and 158. Since different materials react differently to the same stress, the crack stop structure containing different materials cannot rapidly and effectively protect the active circuit region from a crack during the sawing operation done to the scribe line 160 or during the thermal cycles for testing the separated die.

### SUMMARY OF THE INVENTION

Therefore, this invention provides a multi-layer crack stop structure, which is disposed entirely in a die, entirely in the scribe line region outside the die, or partially in the die and partially in the scribe line region.

When the multi-layer crack stop structure is disposed entirely in the die, it may be disposed between the die seal ring structure and the active circuit region, between the two die seal rings of a dual die seal ring structure or between the die seal ring structure and the scribe line region. In such cases, the crack stop structure may be a single ring structure or include a ring portion and four corner portions at the four corners of the die, wherein the corner portions can enhance the crack stop effect at the four corners of the die.

Similarly, when the multi-layer crack stop structure is disposed entirely in the scribe line region, it may be a single ring structure or include a ring portion and four corner portions in the scribe line region outside the four corners of the die, wherein the corner portions can enhance the crack stop effect at the four corners of the die.

When the multi-layer crack stop structure is partially in the die and partially in the scribe line region, a portion thereof in the die may be disposed as in the cases where the crack stop structure is disposed entirely in the die. In some embodiments, the crack stop structure includes four bar-like portions at or outside the four edges of the die and four corner portions outside or at, or partially outside or at, the four corners of the die.

In some embodiments where the crack stop effect at the four corners of the die is enhanced, the multi-layer crack stop structure include a ring portion in the die or in the scribe line region and four corner portions in, or partially in, the scribe line region outside the four corners of the die or in, or partially in, the die.

In some embodiments, the crack stop structure has two ring portions respectively in the die and in the scribe line region for enhancing the crack stop effect all around the die, while the two ring portions may be merged to be a single ring partially in the die and partially in the scribe line region. The crack stop structure may further have four corner portions at four corners of the die or (partially) in the scribe line region outside the four corners of the die to further enhance the crack stop effect at the four corners of the die.

The above variations of the multi-layer crack stop structure of this invention are all macroscopic shape variations in the dimension of a die, approximately in the order of millimeter to sub-millimeter. As for the microscopic structure approximately in the order of micrometer to deep sub-micron, the multi-layer crack stop structure may be formed by contiguously or interleavedly stacking multiple layers of hollow crack stop units in one or more linear regions. When there are multiple linear regions each with crack stop units interleavedly stacked therein, the units in the linear regions may be staggered in a cross section of the crack stop structure. Each hollow crack stop unit in a top view of the crack stop structure may have a contiguous structure or have a segmented structure having multiple segments. The contiguous (or segmented) structure may be a contiguous (or segmented) ring or a contiguous (or segmented) straight or L-shaped line, etc.

The above multi-layer crack stop structure of this invention can effectively avoid the damages like chipping, peeling-off and cracking to the active circuit region when the wafer is being sawn or when the die is subject to thermal cycles for testing. Hence, a better die is obtained, and the reliability of the packaged die is significantly improved.

It is to be understood that both the foregoing general description and the following detailed description are exemplary, and are intended to provide further explanation of the invention as claimed.

### BRIEF DESCRIPTION DRAWINGS

FIG. 1 illustrates a conventional multi-layer crack stop structure on a wafer.

FIG. 2 illustrates a wafer with dies thereon and a representative multi-layer crack stop structure on the wafer according to an embodiment of this invention.

FIG. 3 illustrates a cross section of a die seal ring structure and an interleaved and staggered multi-layer crack stop structure in a first embodiment of this invention.

FIG. 4 illustrates a cross section of a die seal ring structure and a contiguously stacked multi-layer crack stop structure in a second embodiment of this invention.

FIG. 5A illustrates a top view of an interleaved and staggered multi-layer crack stop structure according to a third embodiment of this invention, and FIG. 5B illustrates a cross section of the same along line V-V′.

FIGS. 6A-6F illustrate top views of six macroscopically different examples of the multi-layer crack stop structure of this invention, each including four bar-like portions and four corner portions.

FIGS. 7A-7D illustrate top views of four further examples of the multi-layer crack stop structure of this invention, each including a ring portion and four corner portions.

FIGS. 8A-8B illustrate top views of two further examples of the multi-layer crack stop structure of this invention, each at least having two ring portions respectively in the die and outside the die.

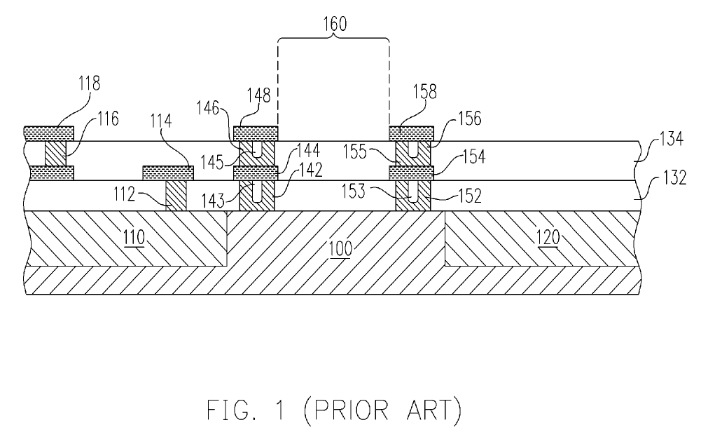

### DESCRIPTION PREFERRED EMBODIMENTS

In some embodiments, the multi-layer crack stop structure is disposed entirely in the die not occupying any area of the scribe line region. Specifically, the multi-layer crack stop can be disposed between the active circuit region and the die seal ring structure, between two die seal rings of a dual die seal ring structure, or between the die seal ring structure and the scribe line region. In certain embodiments, however, the crack stop structure is disposed entirely in the scribe line region not occupying any area of the die.

In other embodiments, the multi-layer crack stop structure is disposed partially in the die and partially in the scribe line region, while a portion thereof in the die may be disposed between the active circuit region and the die seal ring structure, between two die seal rings of a dual die seal ring structure or between the die seal ring structure and the scribe line region. Moreover, a portion of the multi-layer crack stop structure between the die seal ring structure and the scribe line region may be merged with a portion of the same in the scribe line region to form a contiguous structure.

The principle of this invention is described in greater detail in reference of the accompanying drawings. However, the scope of this invention is not limited by them.

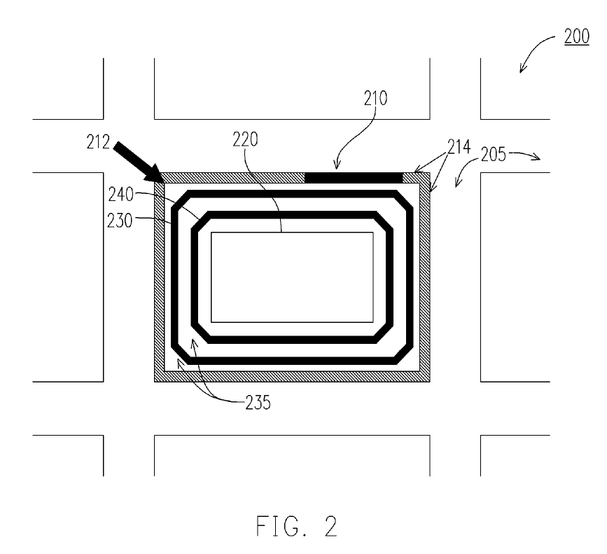

Referring to FIG. 2 that illustrates a wafer with dies thereon and a representative multi-layer crack stop structure in an embodiment of this invention. The dies 210 on the wafer 200 are separated by scribe line regions 205, so that the wafer 200 can be divided into separate dies 210 through sawing. Moreover, pad metals are often disposed at the outer periphery of the active circuit region 220 in the die 210 to form a dual die seal ring structure including two rings 230 and 240. The corner region 235 of the die seal rings 230 and 240 suffering from a maximal stress during the sawing is generally bent to an angle like 45 degrees. It is also possible to form only one die seal ring for one die. Nevertheless, variations of the die seal ring structure in this invention are not limited to the above.

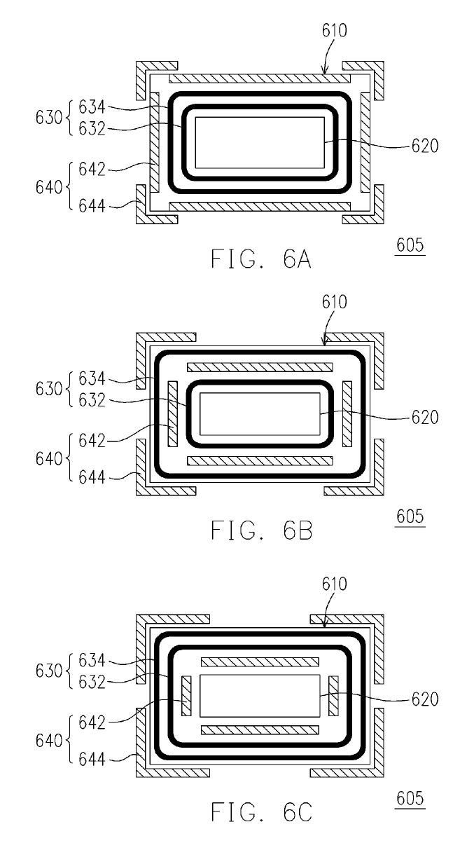

In the embodiment of FIG. 2, the multi-layer crack stop structure 212 is shaped as a ring entirely in the corresponding die 210 and, more specifically, in a region of the die 210 between the outer die seal ring 230 and the scribe line region 205. It is also possible that the outer boundary of the crack stop structure 212 coincides with the outer boundary of the die 210 that is also the inner boundary of the scribe line region 205. However, in other embodiments exemplified by FIGS. 6-8, the multi-layer crack stop structure may be disposed entirely in the scribe line region 205 or partially in the die 210 and partially in the scribe line region 205. In addition, the multi-layer crack stop structure is not limited to have a ring shape but may include multiple bar-like portions, L-shaped portions, shorter slanted bar-like portions or block portions in the top view.

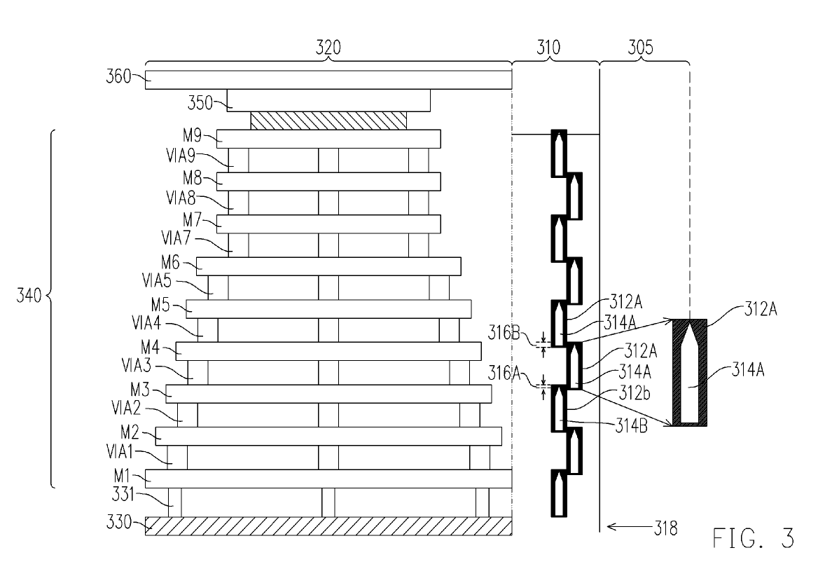

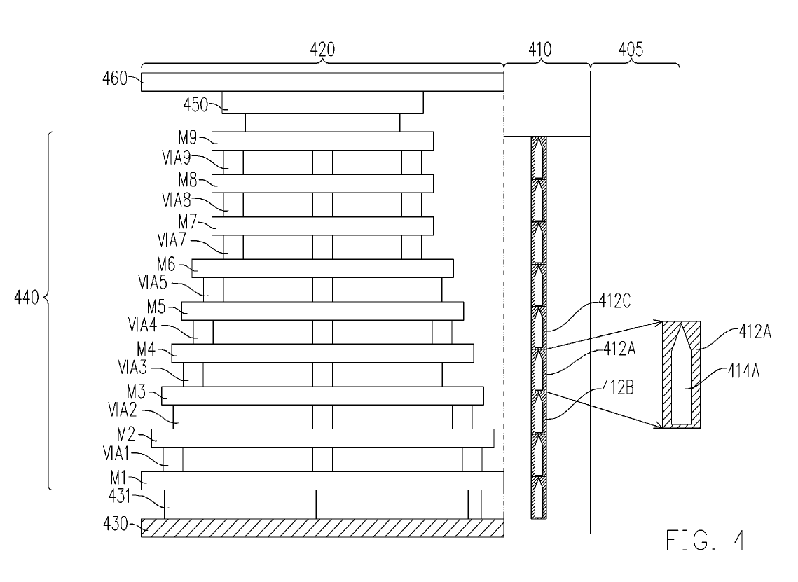

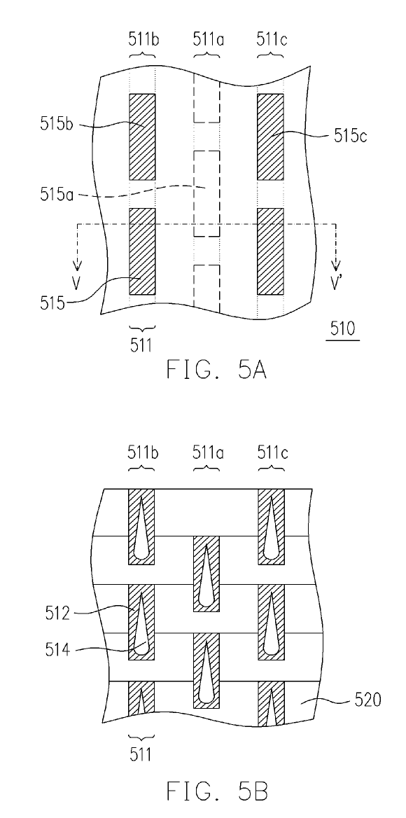

In a microscopic cross-sectional view, the multi-layer crack stop ring structure of this invention may be formed by contiguously or interleavedly stacking multiple layers of hollow crack stop rings in one linear region or in each of multiple linear regions, as shown in FIGS. 3-4. When multiple layers of hollow crack stop rings are interleavedly stacked in each of multiple linear regions, the crack stop rings in the linear regions may be staggered in a cross section of the multi-layer crack stop ring structure, as shown in FIGS. 4 and 5B.

A die seal ring structure and a multi-layer crack stop structure in a microscopic view according to a first embodiment and a second embodiment of this invention are described below in reference of FIG. 3 and FIG. 4, respectively.

FIG. 3 illustrates a cross section of a die seal ring structure and an interleaved and staggered multi-layer crack stop structure in the first embodiment of this invention. The region 310 for forming the crack stop structure is between the die seal ring region 320 and the scribe line region 305, but may be set at another position in alternative embodiments. The interleaved and staggered multi-layer crack stop structure is formed by interleavedly stacking multiple layers of hollow crack stop units in each of two or more linear regions and staggering the crack stop units in all linear regions in a cross section of the crack stop structure at the same time when the die seal ring is formed in the die seal ring region 320. Therefore, the crack stop units in multiple layers may have the same material. The die seal ring is formed at the same time when the metal layers M1-M9 and the via plugs VIA1-VIA8 between each two layers are formed in the die seal ring region 320, and is connected to the substrate 330 via a contact 331 at its bottom. Then, an aluminum (Al) layer 350 and a passivation layer 360 are sequentially formed on the resulting structure.

The overlaid part between each two adjacent crack stop units 312 is an important feature of the interleaved and staggered crack stop structure of the first embodiment. For example, in the stack of adjacent crack stop units 312B, 312A and 312C, when viewed from the direction 318, the overlaid parts 316A and 316B are interleavedly disposed. During the sawing process, the overlaid parts can be rapidly cut off by the mechanical stress due to the sawing, so that chipping is avoided resulting in a better protection.

In the above interleaved and staggered multi-layer crack stop structure, each crack stop unit 312 has a void 314 therein. In an embodiment, the voids 314 of the hollow units 312 are overlaid with each other as view from the direction 318. For example, in the stack of adjacent crack stop units 312B, 312A and 312C, the void 314A is overlaid with the void 314B and the void 314C, respectively, as viewed from the direction 318. Thus, the interleaved and staggered multi-layer crack stop structure is more effective in preventing clipping to provide a better protection.

FIG. 4 illustrates a cross section of a die seal ring structure and a contiguously stacked multi-layer crack stop structure in the second embodiment of this invention. The region 410 for forming the crack stop structure is between the die seal ring region 420 and the scribe line region 405, but may be set at another location in alternative embodiments. The multi-layer crack stop structure is formed by contiguously stacking multiple layers of hollow crack stop units 412 at the same time when the die seal ring is formed in the region 420, so that the crack stop units 412 in multiple layers may have the same material.

The die seal ring is formed at the same time when the multiple metal layers and via plugs between each two layers are interleavedly formed in the die seal ring region 420, and is connected to the substrate 430 via a contact 431 at its bottom. Then, an Al layer 450 and a passivation layer 460 are sequentially formed on the resulting structure. On the other hand, any two adjacent crack stop units are formed contiguously, as illustrated by the stacked structure of the crack stop units 412B, 421A and 412C. During the sawing process, the multi-layer crack stop ring structure can be rapidly cut off by the mechanical stress because of the voids 414 in the crack stop units 412, so that chipping is avoided and a better protection is provided.

FIG. 5A illustrates a top view of an interleaved and staggered multi-layer crack stop structure according to a third embodiment of this invention, and FIG. 5B illustrates a cross section of the same along line V-V′.

Referring to FIGS. 5A-5B, the interleaved and staggered multi-layer crack stop structure 510 includes multiple separate linear stacks 511 of crack stop units, rather than multiple connected linear stacks as shown in FIG. 3. Each linear stack 511 includes an interleaved stack of hollow crack stop units 512 in multiple dielectric layers 520, wherein each crack stop unit 512 has a void 514 therein. As shown in FIG. 5B, the crack stop units 512 in one linear stack 511 may be interleavedly stacked such that every two adjacent dielectric layers 520 has one crack stop unit 512 therein and the crack stop unit 512 is disposed through the upper one of the two adjacent dielectric layers 520 and into but not through the lower one.

Meanwhile, the crack stop units 512 in the multiple linear stacks 511 are staggered in a cross section of the crack stop structure 510. For example, when a crack stop unit 512 in a linear stack 511 a is formed through a dielectric layer and into but not through the underlying one, one adjacent crack stop unit 512 in one adjacent linear stack 511b is disposed through an overlying dielectric layer and into but not through the dielectric layer, and the other adjacent crack stop unit 512 in the linear stack 511b is disposed through the underlying dielectric layer and into but not through the further underlying one. The two adjacent crack stop units 512 in the other adjacent linear stack 511c are likely disposed.

In addition, each crack stop unit 312, 412 or 512 as mentioned above may include a metal layer with a void therein, and may be formed by forming a narrow trench in one or two dielectric layers and then filling in a metal with poor step coverage for forming a void in the metal layer. Moreover, in a microscopic top view, each crack stop unit 312 or 512 in an interleaved and staggered multi-layer crack stop structure may have a contiguous structure like a contiguous ring or a contiguous straight or L-shaped line, etc., or have a segmented structure like a segmented ring or a segmented straight or L-shaped line, etc., that includes multiple separate segments 515.

When each crack stop unit 312 or 512 is a contiguous or segmented ring, straight line or L-shaped line in a microscopic top view, a ring portion, a (slanted) bar-like portion or a L-shaped portion of the multi-layer crack stop structure as illustrated in FIGS. 6-8 in a macroscopic top view can be formed by interleavedly stacking and staggering the crack stop units 312 or 512 in the cross-sectional view to form multiple linear stacks of crack stop units. The segments 515 in multiple linear stacks 511 are preferably also staggered in the top view, as shown in FIG. 5A, so as to completely protect the active circuit region. For example, in the y-direction of FIG. 5A, a segment 515a in a linear stack 511a is positioned between two segments 515b of one layer higher or one layer lower than the segment 515a in one adjacent linear stack 515b and between two segments 515c of one layer higher or one layer lower than the segment 515a in the other adjacent linear stack 515c.

FIGS. 6A-6F illustrate six macroscopically different examples of the multi-layer crack stop structure of this invention, each including four bar-like portions at/outside the four edges of the die and four corner portions (partially) outside/at four corners of the die.

Referring to FIG. 6A, the scribe region, the die and the active circuit region are respectively labeled with 605, 610 and 620, and the die seal ring structure 630 in the die 610 may be a dual die seal ring structure including two rings 632 and 634. The multi-layer crack stop structure 640 includes four bar-like portions 642 at the four edges of the die 610 and four L-shaped portions 644 in the scribe line region 605 outside the four corners of the die 610. An L-shaped portion 644 is preferably overlaid with each adjacent bar-like portion 642 at the x- or y-direction by a certain length, so that a crack generated in the scribe line region 605 can be effectively stopped outside the active circuit region 620.

The four bar-like portions 642 in the die 610 may alternatively be formed between the two die seal rings 632 and 634 of the dual die seal ring structure 630 or between the active circuit region 620 and the die seal ring structure 630, as shown in FIGS. 6B-6C. Moreover, the L-shaped portions 644 in the scribe line region 605 may be replaced by four shorter slanted bar-like portions each having an orientation different from that of any of the four bar-like portions 642. The four slanted bar-like portions 644 may be disposed entirely or partially in the scribe line region 605, or mostly in the scribe line region 605 and slightly overlapping with the region of the die 610, as shown in FIG. 6D.

Analogously, the multi-layer crack stop structure 640 may alternatively include four L-shaped portions 642 at the four corners of the die 610 and four bar-like portions 644 in the scribe line region 605 outside the four edges of the die 610, as shown in FIG. 6E. The four L-shaped portions 642 may similarly be replaced by four shorter slanted bar-like portions entirely or partially in the die 610, or mostly in the die 610 and slightly overlapping with the scribe line region 605, as shown in FIG. 6F.

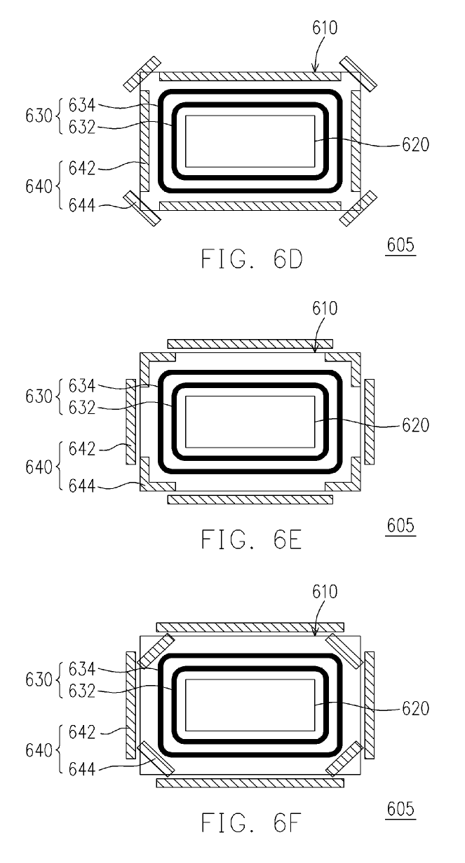

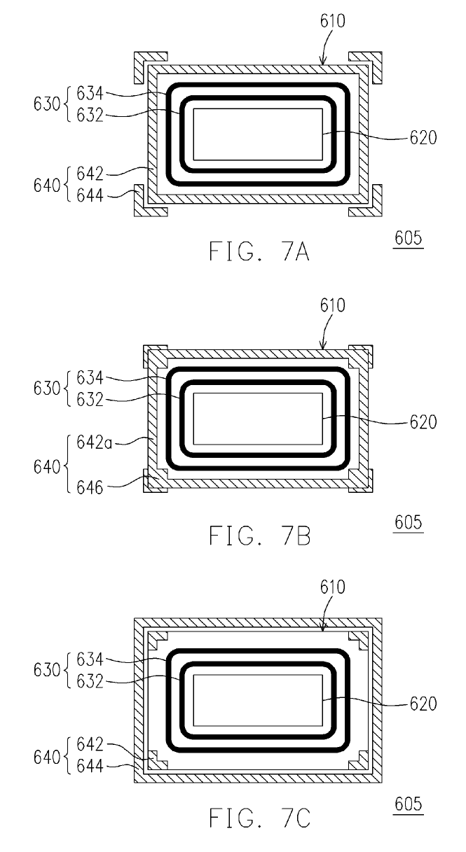

FIGS. 7A-7D illustrate four further macroscopically different examples of the multi-layer crack stop structure of this invention, each including a ring portion in the die or the scribe line region and four corner portions for enforcing the crack stop effect at the four corners of the die. Referring to FIG. 7A, the multi-layer crack stop structure 640 has a ring portion 642 entirely in the die region 610 and four L-shaped portions 644 in the scribe line region 605 outside the four corners of the die 610. The L-shaped portions 644 may be replaced by four shorter slanted bar-like portions, or be replaced by four block portions 646 that are entirely or partially in the die 610, as shown in FIG. 7B. Each block portion 646 may have any shape other than the illustrated one, and may alternatively be disposed entirely in the scribe line region 605. It is noted that a block portion 646 may include a larger number of linear stacks of crack stop units than the ring portion 642a to be wider than the latter.

On the contrary, the multi-layer crack stop structure 640 in FIG. 7C includes four L-shaped portions 642 at the four corners of the die 610 and a ring portion 644 entirely in the scribe line region 605. The four L-shaped portions 642 may also be replaced by four shorter slanted bar-like portions entirely or partially in the die 610, or be replaced by four block portions 648 entirely or partially in the scribe line region 605, as shown in FIG. 7D. Each block portion 648 may have any shape other than the illustrated one, and may alternatively be disposed entirely in the die region 610 apart from the ring portion 644a.

It is also noted that though the above ring, bar-like or L-shaped portion is disposed either entirely in the die 610 or entirely in the scribe line region 605, it may alternatively be disposed partially in the die 610 and partially in the scribe line region 605, while the positions of the other portions of the crack stop structure can be adjusted accordingly.

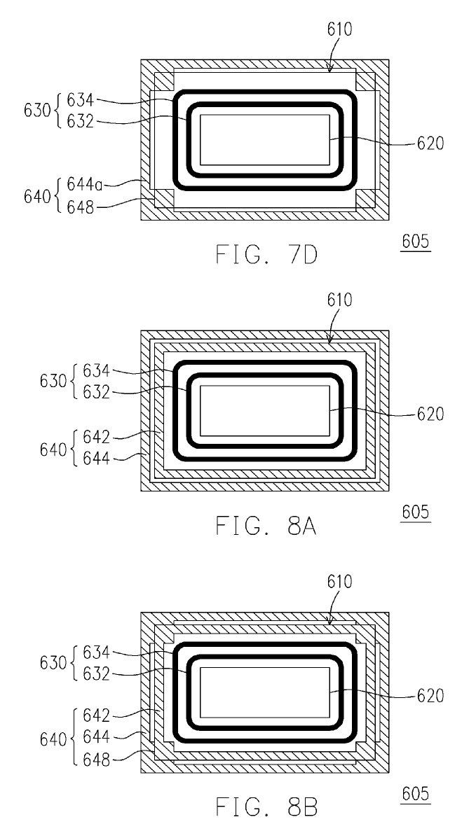

FIGS. 8A-8B illustrate two more macroscopically different examples of the multi- layer crack stop structure, each at least including two ring portions respectively in and outside the die to enhance the crack stop effect all around the active circuit region. In FIG. 8A, the crack stop structure 640 has two ring portions 642 and 644 only respectively in and outside the die 610. The two ring portions 642 and 644 may be merged to form a single ring that is partially in the die 610 and partially in the scribe line region 605.

Moreover, the multi-layer crack stop structure 640 may further include four block portions 648 entirely or partially in the scribe line region 605 outside the four corners of the die 610, as shown in FIG. 8B, to further enhance the crack stop effect at the four corners of the die 610. Each block portion 646 may have any shape other than the illustrated one, and may alternatively be disposed entirely in the die 610.

In summary, a multi-layer crack stop structure disposed entirely in a die, entirely in the scribe line region around the die or partially in the die and partially in the scribe line region is provided by this invention. The multi-layer crack stop structure can effectively prevent certain damages like chipping, delamination, or peeling-off from occurring to the active circuit region during wafer sawing or thermal cycles for testing, so that a better single die is obtained and the reliability of the packaged die is significantly improved.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A multi-layer crack stop structure for a die surrounded by a scribe line region and comprising an active circuit region and a die seal ring structure around the active circuit region, the multi-layer crack stop structure
surrounding the active circuit region;
being formed from a plurality of layers of hollow crack stop units; and
being disposed only in the die with four corner portions at four corners of the die that can enhance crack stop effect at the four corners of the die, only in the scribe line region, or partially in the die and partially in the scribed line region.

2. The multi-layer crack stop structure of claim 1, a portion thereof in the die being disposed between the active circuit region and the die seal ring structure, between two die seal rings of a dual die seal ring structure as the die seal ring structure, or between the die seal ring structure and the scribed line region.

3. The multi-layer crack stop structure of claim 1, including four bar-like portions at four edges of the die and four corner portions entirely or partially in the scribe line region outside the four corners of the die.

4. The multi-layer crack stop structure of claim 3, wherein the four corner portions include four L-shaped portions, or include four slanted bar-like portions each having an orientation different from an orientation of any of the four bar-like portions.

5. The multi-layer crack stop structure of claim 1, including four bar-like portions in the scribe line region outside four edges of the die and four corner portions entirely or partially at the four corners of the die.

6. The multi-layer crack stop structure of claim 5, wherein the four corner portions include four L-shaped portions, or include four slanted bar-like portions each having an orientation different from an orientation of any of the four bar-like portions.

7. The multi-layer crack stop structure of claim 1, including a ring portion in the die and four corner portions that are at the four corners of the die or are entirely or partially in the scribe line region outside the four corners of the die.

8. The multi-layer crack stop structure of claim 7, wherein the four corner portions include four L-shaped portions, four slanted bar-like portions or four block portions.

9. The multi-layer crack stop structure of claim 1, including a ring portion in the scribe line region and four corner portions that are entirely or partially in the scribe line region outside the four corners of the die or are at the four corners of the die.

10. The multi-layer crack stop structure of claim 9, wherein the four corner portions include four L-shaped portions, four slanted bar-like portions or four block portions.

11. The multi-layer crack stop structure of claim 1, including a first ring portion in the die and a second ring portion in the scribe line region.

12. The multi-layer crack stop structure of claim 11, further including four block portions that are at the four corners of the die or are entirely or partially in the scribe line region outside the four corners of the die.

13. The multi-layer crack stop structure of claim 1, comprising one or a plurality of linear stacks of hollow crack stop units, wherein a linear stack includes a plurality of layers of hollow crack stop units.

14. The multi-layer crack stop structure of claim 13, wherein the hollow crack stop units in a linear stack are disposed contiguously.

15. The multi-layer crack stop structure of claim 13, wherein the hollow crack stop units in one of the plurality of linear stacks are disposed interleavedly.

16. The multi-layer crack stop structure of claim 15, wherein the hollow crack stop units in the plurality of linear stacks are staggered in a cross section of the multi-layer crack stop structure.

17. The multi-layer crack stop structure of claim 16, wherein in a top view of the multi-layer crack stop structure, each hollow crack stop unit has a contiguous structure or has a segmented structure including a plurality of segments.

18. The multi-layer crack stop structure of claim 17, wherein the contiguous structure is a contiguous ring or a contiguous straight or L-shaped line, and the segmented structure is a segmented ring or a segmented straight or L-shaped line.

19. The multi-layer crack stop structure of claim 17, wherein the segments of the hollow crack stop units in the plurality of linear stacks are staggered in the top view.

20. The multi-layer crack stop structure of claim 15, wherein in one of the plurality of linear stacks, the hollow crack stop units are disposed in a plurality of dielectric layers wherein every two adjacent dielectric layers has a hollow crack stop unit therein that is disposed through the upper one of the two adjacent dielectric layers and into but not through the lower one of the two adjacent dielectric layers.
